(19) United States
(12) Patent Application Publication
(10) Pub. No.: US 2006/0172470 A1
(43) Pub. Date: Aug. 3, 2006

(54) Method of manufacturing thin film element

(75) Inventors: Yujiro Hara, Yokohama-Shi (JP); Yutaka Onozuka, Yokohama-Shi (JP); Kentaro Miura, Kawasaki-Shi (JP); Masahiko Akiyama, Tokyo (JP)

Correspondence Address: AMIN & TUROCY, LLP, 1900 EAST 9TH STREET, NATIONAL CITY CENTER, 24TH FLOOR,, CLEVELAND, OH, 44114, US

(73) Assignee: Kabushiki Kaisha Toshiba, Minato-ku (JP)

(21) Appl. No.: 11/330,843

(22) Filed: Jan. 12, 2006

(30) Foreign Application Priority Data
Jan. 13, 2005 (JP) 2005-006876

(51) Int. Cl. H01L 21/84

(52) U.S. Cl. 438/149; 257/E21.415

(57) ABSTRACT

A method of manufacturing a thin film element is proposed, which can prevent the decrease in TFT manufacturing yield caused by the cracks occurring in an isolation layer at the time of the removing of an element formation substrate. A protection layer is formed between a plurality of TFTs, and an isolation layer is formed below the TFTs and the protection layer. This structure can prevent the TFTs from suffering adverse effects when the TFTs are temporarily bonded to an intermediate transfer substrate, and the element formation substrate and the isolation layer are removed.

### CROSS-REFERENCE TO RELATED APPLICATION

This application is based upon and claims the benefit of priority from prior Japanese Patent Application No. 2005-6876, filed on Jan. 13, 2005 in Japan, the entire contents of which are incorporated herein by reference.

### BACKGROUND OF THE INVENTION

1. Field of the Invention

The present invention relates to a method of manufacturing a thin film element such as an active matrix element.

2. Background Art

Liquid crystal displays and organic EL displays are used in various types of display apparatuses such as laptop personal computers, mobile information terminals, monitors, televisions, mobile phones, etc., because they are thin, consume lower power, and have a color display capability. In a liquid crystal display or organic EL display, which is required to make a higher-definition display, an active matrix substrate is used. This substrate is obtained by arranging thin film transistors (TFTs), each having an active layer of amorphous silicon or polycrystalline silicon, in a matrix form on a glass substrate. Active matrix substrates are expected to meet such requirements as lower power consumption, higher-definition display, larger screen size, lighter weight, thinness, and lower manufacturing cost.

In order to meet such requirements, a method of manufacturing an element-transferring type active matrix element is disclosed, in, for example, Japanese Patent Laid-Open Publication No. 2001-7340. In this manufacturing method, amorphous silicon TFTs are formed on an element formation substrate, transferred to an intermediate transfer substrate, and further transferred to a final transfer substrate, on which wiring lines have been formed, thereby finally forming active matrix elements.

When an active matrix element is formed by using the aforementioned method, it is possible to increase the size of the final transfer substrate without being limited by the size of the element formation substrate. Furthermore, it is possible to reduce the cost of the formation of amorphous silicon TFTs, which is high compared to the cost of the formation of wiring lines. This is achieved by forming amorphous silicon TFTs, which require high-temperature processing to form, in a high density formation on an element formation substrate, which is highly resistant to heat, and selecting which amorphous silicon TFTs are to be transferred to a final transfer substrate. With this method, it is possible to use a plastic film, the heat resistance of which is relatively low, as the final transfer substrate. It is further possible to combine this method with other printing techniques such as the roll-to-roll printing technique. Thus, it is possible to form an active matrix element at a low cost.

On the other hand, when the method disclosed in Japanese Patent Laid-Open Publication No. 2001-7340 is employed, there is a problem in that when the element formation substrate is removed by etching, for example, the amorphous silicon TFTs are damaged, and peeled off from the adhesion/exfoliation layer or cracked.

In order to solve the aforementioned problem, a method is proposed (as disclosed in, for example, Japanese Patent Laid-Open Publication No. 2004-119936), in which the element formation substrate is removed by using an etchant, for example, with the isolation layer between the element formation substrate and the amorphous silicon TFTs being left even in the region other than the region where the amorphous silicon TFTs are formed. In this method, since the isolation layer is left in the regions between adjacent amorphous silicon TFTs, the amorphous silicon TFTs are not directly exposed to the etchant when the element formation substrate is removed.

However, when the method disclosed in Japanese Patent Laid-Open Publication No. 2004-119936 is employed, the following problem arises. If the element formation substrate is removed after adjacent TFTs are isolated in the plane of the substrate, only the isolation layer is left between the adjacent TFTs. Accordingly, the strength of the structure supporting the regions between the adjacent TFTs becomes insufficient. Accordingly, there is a problem in that the isolation layer is cracked in the regions between adjacent TFTs due to a chemical factor such as the exposure to the etchant when the element formation substrate is removed, and physical factors such as heat and stress.

### SUMMARY OF THE INVENTION

In consideration of the aforementioned problems, the object of the present invention is to provide a method of manufacturing a thin film element that can prevent the degradation in TFT manufacture yield caused by cracks in an isolation layer when an element formation substrate is removed.

In order to solve the aforementioned problems, a method of manufacturing a thin film element according to an aspect of the present invention includes:

sequentially forming an isolation layer and an undercoat layer on an element formation substrate;

forming thin film elements on the undercoat layer;

separating the thin film elements in a plane of the substrate with the isolation layer being left on the entire surface of the element formation substrate;

forming a protection layer between adjacent thin film elements, which have been separated from each other;

temporarily bonding an intermediate transfer substrate to the thin film elements at a side opposite to the element formation substrate; and

removing only the element formation substrate, thereby transferring the thin film elements to the intermediate transfer substrate.

### BRIEF DESCRIPTION OF THE DRAWINGS

FIG. 1 is a sectional view showing a step of a method of manufacturing a thin film element according to a first embodiment of the present invention.

FIG. 2 is a sectional view showing a step of the method of manufacturing a thin film element according to the first embodiment of the present invention.

FIG. 3 is a sectional view showing a step of the method of manufacturing a thin film element according to the first embodiment of the present invention.

FIG. 4 is a sectional view showing a step of the method of manufacturing a thin film element according to the first embodiment of the present invention.

FIG. 5 is a sectional view showing a step of the method of manufacturing a thin film element according to the first embodiment of the present invention.

FIG. 6 is a plan view showing the method of manufacturing a thin film element according to the first embodiment of the present invention.

FIG. 7 is a sectional view taken along line A-A′ of FIG. 6.

FIG. 8 is a sectional view showing a step of the method of manufacturing a thin film element according to the first embodiment of the present invention.

FIG. 9 is a sectional view of an intermediate transfer substrate according to the first embodiment of the present invention.

FIG. 10 is a sectional view showing a step of the method of manufacturing a thin film element according to the first embodiment of the present invention.

FIG. 11 is a sectional view showing a step of the method of manufacturing a thin film element according to the first embodiment of the present invention.

FIG. 12 is a sectional view showing a step of the method of manufacturing a thin film element according to the first embodiment of the present invention.

FIG. 13 is a sectional view showing a step of the method of manufacturing a thin film element according to the first embodiment of the present invention.

FIG. 14 is a plan view of a final transfer substrate according to the first embodiment of the present invention.

FIG. 15 is an enlarged view around a scanning line and a storage capacitor line formed on the final transfer substrate shown in FIG. 14.

FIG. 16 is a sectional view taken along line A-A of FIG. 15.

FIG. 17 is a plan view of the state in which an adhesion layer is formed on the transfer substrate shown in FIG. 15.

FIG. 18 is a sectional view taken along line B-B of FIG. 17.

FIG. 19 is a top view of a step of transferring the TFTs on the intermediate transfer substrate to the final transfer substrate.

FIG. 20 is a sectional view taken along line C-C of FIG. 19.

FIG. 21 is a plan view of the intermediate transfer substrate after the transferring step shown in FIGS. 19 and 20.

FIG. 22 is a plan view of the final transfer substrate after the transferring step shown in FIGS. 19 and 20.

FIG. 23 is a sectional view taken along line D-D of FIG. 22.

FIG. 24 is a sectional view showing a wiring line forming step in the method of manufacturing a thin film element according to the first embodiment of the present invention.

FIG. 25 is a plan view showing a wiring line forming step in the method of manufacturing a thin film element according to the first embodiment of the present invention.

FIG. 26 is a sectional view taken along line E-E of FIG. 25.

FIG. 27 is a plan view showing the wiring line forming step in the method of manufacturing a thin film element according to the first embodiment of the present invention.

FIG. 28 is a sectional view taken along line F-F of FIG. 27.

FIG. 29 is a plan view showing a wiring line forming step in the method of manufacturing a thin film element according to the first embodiment of the present invention.

FIG. 30 is a sectional view taken along line G-G of FIG. 29.

FIG. 31 is a sectional view showing a step of a method of manufacturing a thin film element according to a second embodiment of the present invention.

FIG. 32 is a sectional view showing a step of the method of manufacturing a thin film element according to the second embodiment of the present invention.

FIG. 33 is a sectional view showing a step of the method of manufacturing a thin film element according to the second embodiment of the present invention.

FIG. 34 is a sectional view showing a step of the method of manufacturing a thin film element according to the second embodiment of the present invention.

FIG. 35 is a sectional view showing a step of a method of manufacturing a thin film element according to a third embodiment of the present invention.

FIG. 36 is a sectional view showing a step of the method of manufacturing a thin film element according to the third embodiment of the present invention.

FIG. 37 is a sectional view showing a step of a method of manufacturing a thin film element according to a third embodiment of the present invention.

FIG. 38 is a sectional view showing a step of a method of manufacturing a thin film element according to a fourth embodiment of the present invention.

FIG. 39 is a sectional view showing a step of the method of manufacturing a thin film element according to the fourth embodiment of the present invention.

FIG. 40 is a sectional view showing a step of the method of manufacturing a thin film element according to the fourth embodiment of the present invention.

FIG. 41 is a sectional view showing a step of the method of manufacturing a thin film element according to the fourth embodiment of the present invention.

FIG. 42 is a sectional view showing a step of the method of manufacturing a thin film element according to the fourth embodiment of the present invention.

FIG. 43 is a sectional view showing a step of the method of manufacturing a thin film element according to the fourth embodiment of the present invention.

### DESCRIPTION OF THE EMBODIMENTS

Hereinafter, embodiments of the present invention will be described with reference to the accompanying drawings.

### First Embodiment

With respect to this embodiment, the description will explain the steps of forming an isolation layer and an undercoat layer on an element formation substrate, then forming amorphous silicon TFTs (hereinafter referred to as “TFTs”) on the element formation substrate, then transferring the TFTs onto the intermediate transfer substrate, and then transferring the TFTs onto a final transfer substrate, thereby forming an active matrix.

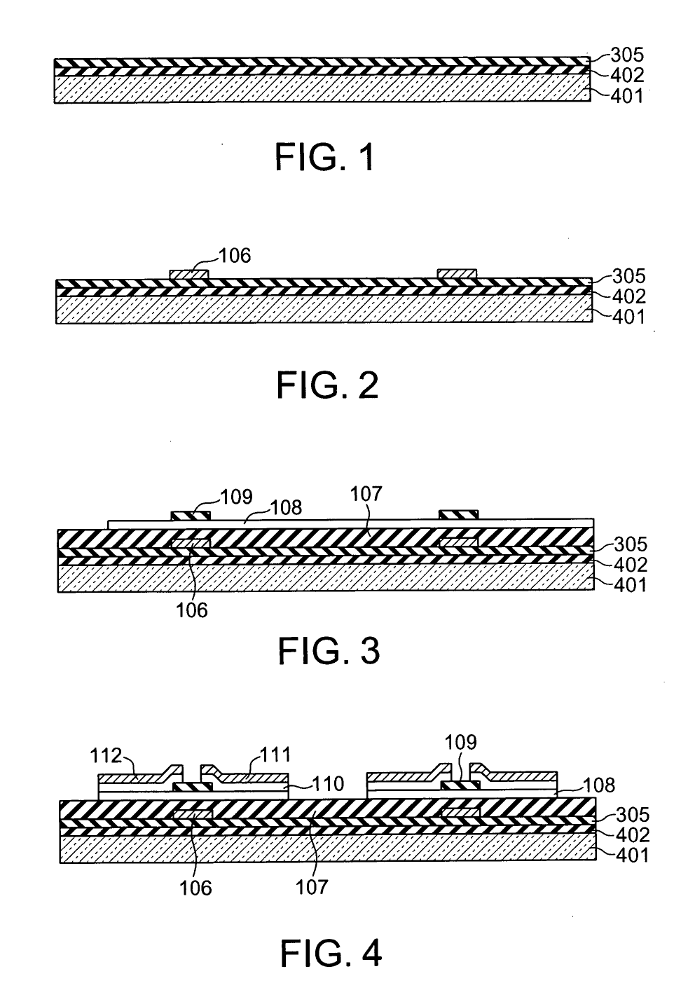

First, as shown in the sectional view of FIG. 1, an isolation layer 402 having a thickness of about 100 nm, and un undercoat layer 305 having a thickness of about 100 nm are formed on an element formation substrate 401 of non-alkali glass. The isolation layer 402 has a function to separate TFTs from the element formation substrate 401 in the element formation substrate removal step, which will be described later. If a method utilizing the decrease in adhesion force between the TFTs and the element formation substrate 401 caused by laser irradiation such as excimer laser irradiation is employed as a method of removing the substrate, amorphous silicon or the like can be used as the isolation layer 402 material. If a method utilizing an etching technique to remove the element formation substrate 401 is employed, a metal oxide film such as a tantalum oxide film or a silicon nitride film can be used since the isolation layer 402 serves as an etching stopper when the element formation substrate 401 is etched. With respect to the undercoat layer 305, a silicon oxide film or a silicon nitride film can be used. Although non-alkali glass is used to form the element formation substrate 401 in this embodiment, the material is not limited thereto, and other materials, such as silicon, can also be used.

Next, as shown in FIG. 2, a gate electrode 106 having a thickness of about 100 nm-500 nm is formed by forming a metal thin film of a material such as a Mo—W alloy, a Mo—Ta alloy, an Al—Nd alloy by a sputtering method, and patterning the thus-formed metal thin film. Subsequently, as shown in FIG. 3, a gate insulating film 107 formed of silicon oxide or silicon nitride having a thickness of about 100 nm-500 nm is formed by a plasma CVD method so as to cover the gate electrode. Thereafter, an amorphous silicon layer serving as a semiconductor layer 108 having a thickness of about 30 nm-200 nm, and a silicon nitride film serving as a channel protecting insulating film 109 having a thickness of 30 nm-200 nm are sequentially formed, and the channel protecting insulating film 109 is processed by backside exposure so as to be self-aligned with the gate electrode 106.

Then, as show in FIG. 4, a phosphorus-doped n-type semiconductor layer 110 having a thickness of 30 nm-100 nm is formed by chemical vapor deposition (CVD), and a metal thin film having a thickness of about 100 nm-500 nm is formed thereon. Thereafter, the metal thin film is patterned to form a source electrode 111 and a drain electrode 112, and the n-type semiconductor layer 110 and the amorphous silicon layer 108 are also patterned.

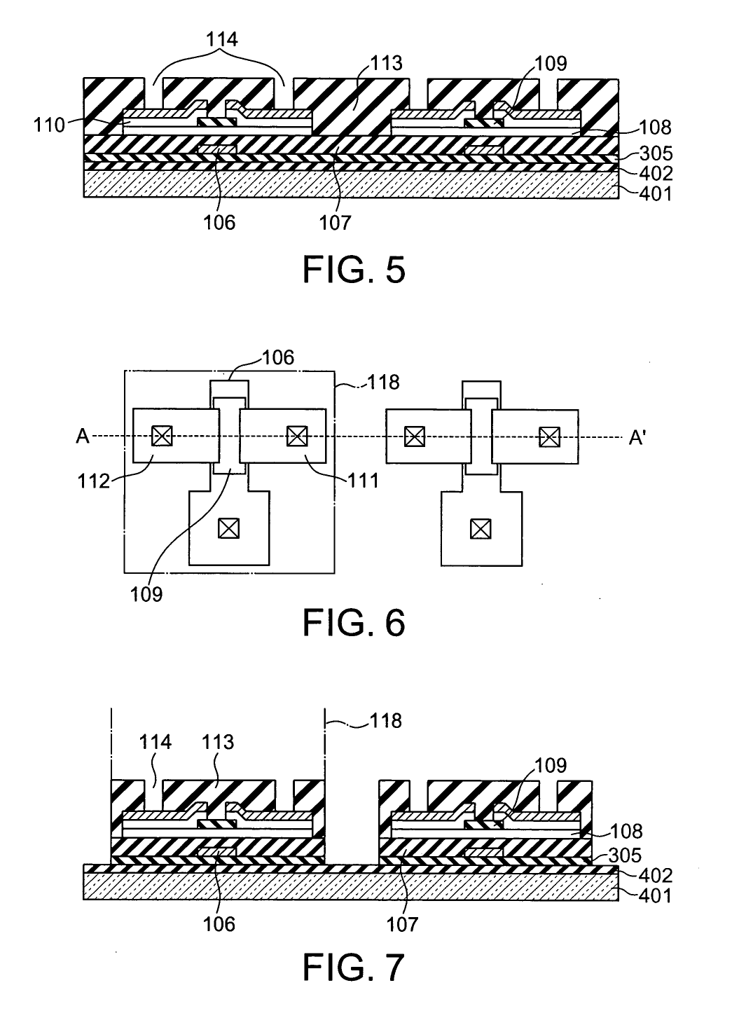

Subsequently, as shown in FIG. 5, a silicon nitride film serving as a passivation film 113 having a thickness of 100 nm-300 nm is formed by plasma CVD, and contact holes 114 are formed at the portions of the source electrode 111, the drain electrode 112, and the gate electrode 106. Thus, TFTs 102 are formed.

After the TFTs 102 are formed, the portions of the passivation film 113, the gate insulating film 107, and the undercoat layer 305 located outside isolation edges 118 of each TFT are removed by etching, as shown in the plan view of FIG. 6 and the sectional view of FIG. 7, thereby separating each TFT in the direction of the substrate plane. Wet etching using an etchant containing hydrofluoric acid such as BHF (hydrofluoric acid/ammonia fluoride solution), or dry etching including reactive ion etching and chemical dry etching using a gas containing fluoride such as sulfur hexafluoride (SF₆) gas, carbon tetrafluoride (CF₄) gas, etc. can be employed in this process. The isolation layer 402 is left on the entire surface of the element formation substrate 401. In this embodiment, the size of each TFT 102 surrounded by the isolation edges 118 is 40 μm×40 μm, and the interval between adjacent TFTs 102 is 20 μm. That is to say, the TFTs 102 are formed in a matrix on the element formation substrate 401 in a cycle of 60 μm.

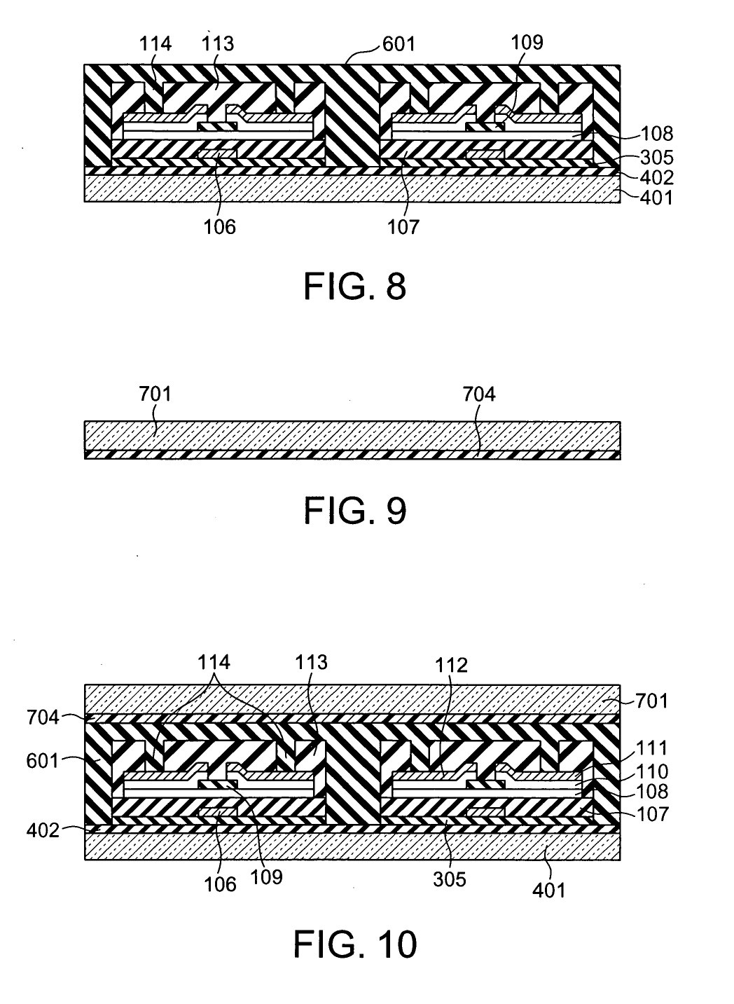

Subsequently, as shown in FIG. 8, a protection layer 601 of an organic resin is formed on the entire surface of the element formation substrate 401. Examples of the organic resin that can be used are: a novolac resin; a polyimide resin; an acrylic resin; a cresol resin; a toluene resin; a phenol resin; a vinyl resin; an epoxy resin; an alkyd resin; a vinyl acetate resin; a melamine resin; a styrene resin; a fluorine resin; and a resin containing polynorbornene, poly-parahydroxystyrene, methacrylate, but the organic resin is not limited to these materials. It is preferable that the protection layer 601 have a chemical resistant property if the element formation substrate is removed by using an etchant in a substrate removing step, which will be described later. Furthermore, it is preferable that the protection layer 601 have a good adhesion property with respect to the TFTs 102 and the isolation layer 402, which are located thereunder, and can be removed without leaving any residue in a removal step performed later, by being ashed using oxygen plasma or by being dissolved in a solvent. The protection layer 601 has a thickness of about 0.05 μm-5 μm. In this case, the protection layer 601 of a phenyl resin having a thickness of 0.5 μm is formed by applying a mixed liquid of a phenol resin and a solvent by the spin coating method, and then performing a baking operation to volatize the solvent.

After the protection layer is formed, an intermediate transfer substrate 701, on which a temporary adhesive layer 704 is formed, is prepared as shown in FIG. 9. It is preferable that the viscosity or adhesion force of the surface of the temporary adhesive layer 704 be changeable, i.e., to form the temporary adhesive layer 704, it is preferable to use a material whose viscosity or adhesion force can be changed by applying heat or light from the outside. The material of the intermediate transfer substrate 701 can be non-alkali glass, quartz, soda lime, Si substrate, stainless plate, aluminum plate, aluminum foil, a plastic film of PET, PEN, polyester, and so on. When the viscosity or adhesion force of the temporary adhesive layer is decreased by the irradiation of light, a material that passes light having a desired wavelength can be selected.

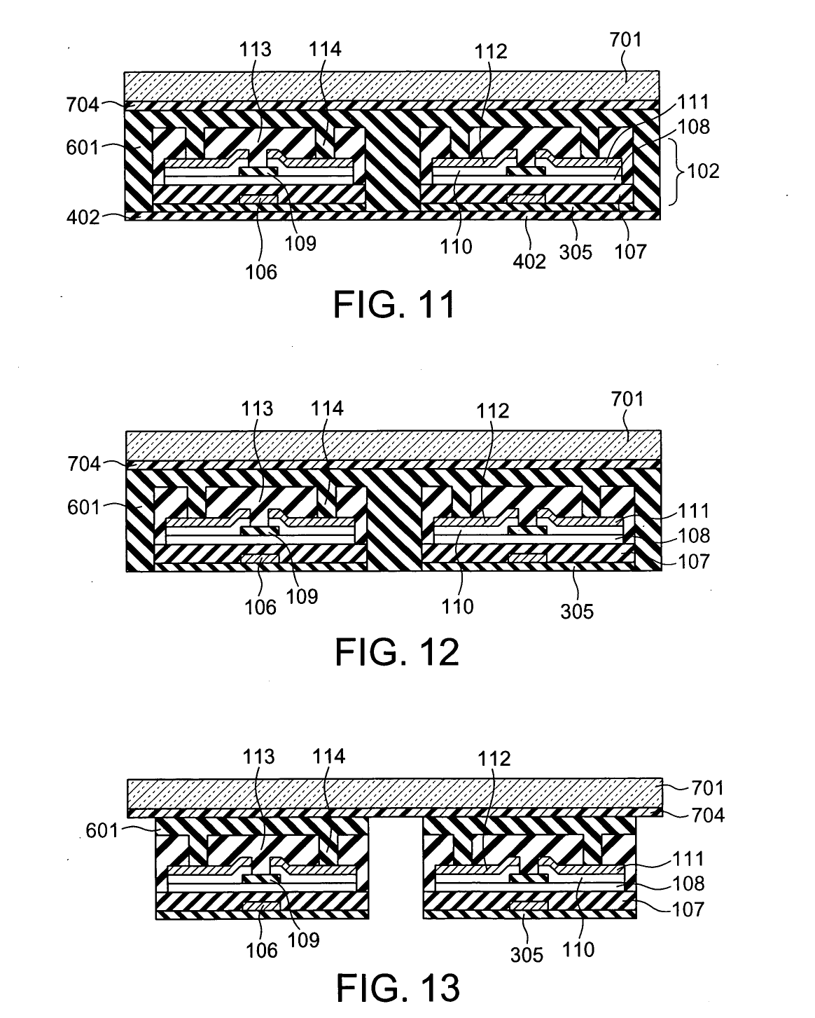

Next, as shown in FIG. 10, the element formation substrate 401 and the intermediate transfer substrate 701 are bonded to each other so that the protection layer 601 and the temporary adhesive layer 704 face each other. Subsequently, as shown in FIG. 11, the TFTs 102 bonded to the intermediate transfer substrate are separated from the element formation substrate 401. If the isolation layer 402 is formed of amorphous silicon, irradiation by excimer laser causes ablation (interface friction) between the amorphous silicon of the isolation layer 402 and the non-alkali glass of the element formation substrate 401, thereby degrading the adhesion force between the isolation layer 402 and the undercoat layer 305. It is possible to remove the TFTs 102 from the element formation substrate in this way. Alternatively, the element formation substrate can be removed by an etching operation using an etchant containing a hydrofluoric acid. In such a case, the isolation layer 402 serves as an etching stopper at the time of the etching of the element formation substrate, so that a metal oxide film such as a tantalum oxide film, a nitride film, a silicon layer, a silicon nitride layer, or a layer obtained by laminating these layers can be used.

In the substrate removing step shown in FIG. 11, the protection layer 601 of an organic resin exists in the portion between adjacent TFTs 102 in addition to the isolation layer 402. Accordingly, the degree of the strength is improved as compared to the case where only the isolation layer 402 exists there. As a result, the possibility of causing damage such as cracks or peeling-off by a chemical factor such as the exposure to an etchant or a physical factor such as heat or stress can be reduced. If there is a pinhole in the isolation layer 402, the side portions of the TFTs are not likely to suffer damage due to the exposure to the etchant since the protection layer 601 exists between adjacent TFTs.

Then, as shown in FIG. 12, the isolation layer 402 is removed by wet etching using TMAH (tetra-methyl ammonium hydroxide) or the like, or dry etching such as reactive ion etching and chemical dry etching using a gas containing fluoride such as sulfur hexafluoride gas and carbon tetrafluoride gas. As a result, an undercoat layer 305 is exposed in the portion where the isolation layer 402 has been removed and where there are TFTs, and a protection layer 601 is exposed in the portion where the isolation layer 402 has been removed and where there is no TFT.

After the isolation layer 402 is removed, the protection layer 601 formed between adjacent TFTs is removed, as shown in FIG. 13. The protection layer 601 can be removed by ashing, i.e., the irradiation of the intermediate transfer substrate 701 from the TFT side with plasma containing oxygen, or by the dissolving of the substrate into a solvent. In both cases, it is possible to remove only the protection layer 601 under the condition that the undercoat layer 305 formed of silicon oxide or silicon nitride does not suffer any damage. In particular, when the ashing is performed, since the undercoat layer 305 serves as a hard mask with respect to oxygen plasma, it is possible to remove the protection layer 601 between adjacent TFTs 102 in a self-aligned manner without causing damage to the TFTs 102. Thus, as shown in FIG. 13, it is possible to transfer the TFTs 102 to the intermediate transfer substrate 701 so as to be separated in the plane of the substrate.

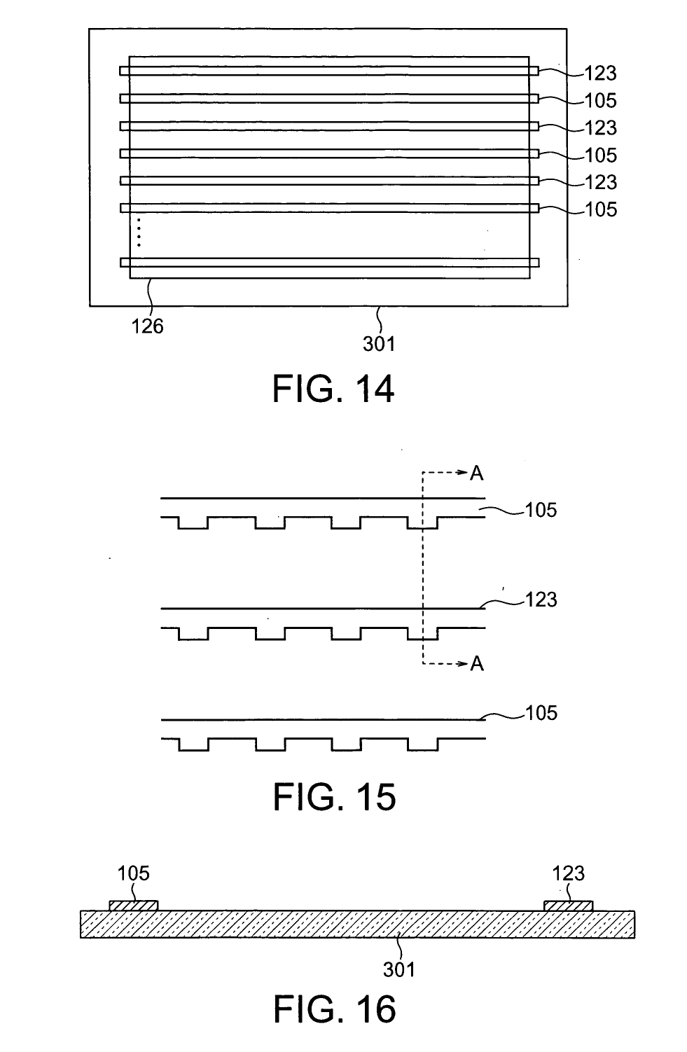

Subsequently, the process of transferring the TFTs from the intermediate transfer substrate 701 to the final transfer substrate to form an active matrix substrate will be described below. FIG. 14 shows a plan view of a final transfer substrate 301, FIG. 15 shows an enlarged plan view of scanning lines 105 and a storage capacitor line 123, and FIG. 16 shows a sectional view taken along line A-A of FIG. 15. As shown in FIG. 14, an element transferring area 126, in which the scanning lines 105 and the storage capacitor lines 123 are alternately formed in parallel with each other, is formed in the final transfer substrate 301. In the element transferring area 126, the interval between adjacent TFTs in a direction the scanning lines 105 and the storage capacitor lines 123 extend is set to be 120 μm, and the number of TFTs in this direction is set to be 5,760. The interval between adjacent TFTs in a direction perpendicular to the direction the scanning lines 105 and the storage capacitor lines 123 extend is set to be 360 μm, and the number of TFTs in this direction is set to be 1,080. Accordingly, the diagonal length thereof becomes 31.2 inches. The final transfer substrate 301 can be formed of non-alkali glass, plastic film, etc.

As shown in FIG. 16, a metal thin film is formed on the final transfer substrate 301 by evaporation or sputtering, and a resist pattern is formed thereon by photolithography. Thereafter, the metal thin film is etched by using the resist pattern, thereby forming the scanning lines 105 and the storage capacitor lines 123 each having a thickness of about 0.1 μm-5 μm and a line width of about 10 μm-30 μm. The scanning lines 105 and the storage capacitor lines 123 can also be formed by a screen printing method or ink jet method. Specifically, a wiring line pattern of the scanning lines 105 and the storage capacitor lines 123 is formed with a conductive paste, and then annealing thereof is performed at a temperature of about 150-600° C. for about 30 minutes. It is possible to effectively transfer the TFTs to the element formation substrate 401 when the cycle of the scanning lines 105 is set to be an integral multiple of the cycle of the TFTs 102. In this embodiment, the cycle of the scanning lines 105 formed on the final transfer substrate 301 is 360 μm, and the cycle of signal lines 104, which will be described later, is 120 μm. Since the cycle of the TFTs 102 formed on the element formation substrate 401 is 60 μm in both the vertical and horizontal directions, the cycle of the scanning lines 105 is six times that of the TFTs 102, and the cycle of the signal lines 104 is two times that.

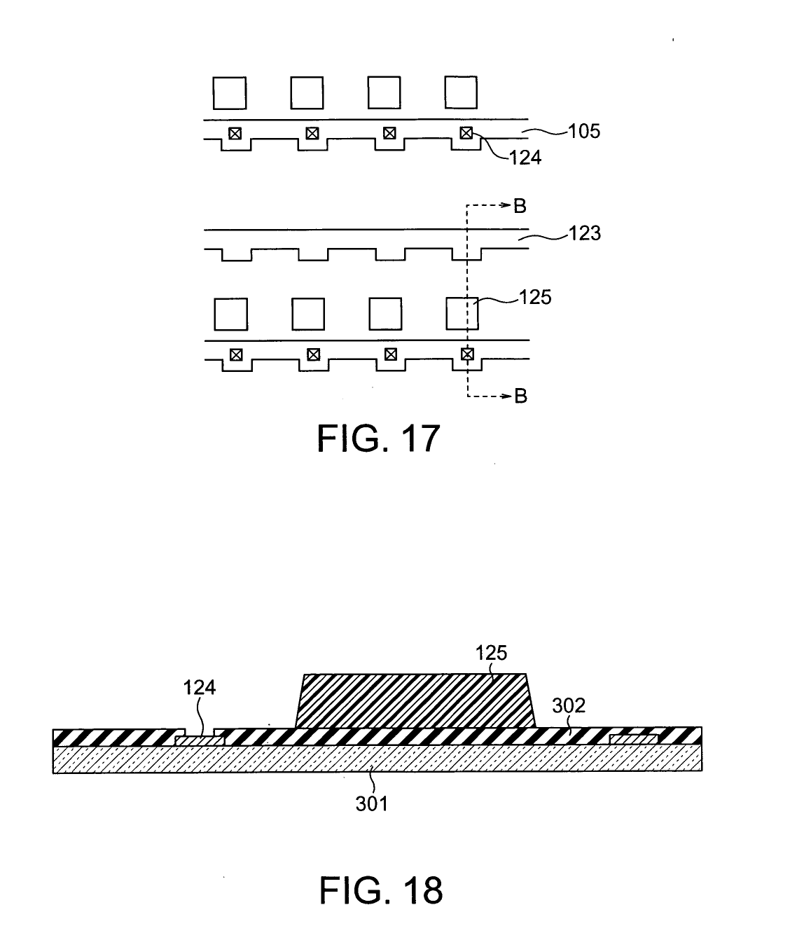

FIG. 17 is a plan view of the final transfer substrate 301 after an adhesion layer 125 is formed. FIG. 18 is a sectional view taken along line B-B of FIG. 17. As shown in FIGS. 17 and 18, after the scanning lines 105 and the storage capacitor lines 123 are formed, an interlayer insulating film 302 having a thickness of 0.2 μm-0.5 μm is formed on the scanning lines 105, and the adhesion layer 125 is formed in a region where the TFTs are transferred on the final transfer substrate 301. The area of the lower surface of the adhesion layer 125 is about the same as that of the TFT, i.e., about 40 μm×40 μm, and the thickness thereof is about 1 μm-5 μm. The interlayer insulating film 302 can be formed of a non-organic insulating film by a plasma CVD method or sputtering method. Alternatively, an organic film of polyimide, an acrylic resin, benzo-cyclobutene (BCB) and the like can also be used. After the interlayer insulating film 302 is formed, contact through-holes 124 are formed through the interlayer insulating film so that the surfaces of the scanning lines 105 are exposed near the region where the TFTs 102 are to be transferred. The adhesion layer 125 can be formed by a coating method such as screen printing, or by first applying a photosensitive acrylic and then exposing the layer to light. The adhesion layer 125 can contain fine particles of a metal such as Cr, or black resist. By using the aforementioned methods to blacken the resist or make the resist opaque, it is possible to decrease the leakage of light into active matrix elements transferred thereon, thereby improving the switching ratio of the transistors, resulting in that the image quality of the display apparatus finally manufactured can be improved. If a photosensitive organic resin is used to form the adhesion layer 125, it is possible to perform the patterning thereof using photolithography, which is a simple and easy way, thereby decreasing the manufacturing cost as compared to the case where a non-photosensitive resin is used. Of course, when an non-photosensitive organic resin is used, the patterning can be performed by etching or printing. For example, in the case where the forming cycle is 120 μm in the horizontal direction and 360 μm in the vertical direction, and there are 5,760 TFTs in the horizontal direction and 1,080 in the vertical direction to form a matrix shape, the element transferring area has a diagonal length of 31.2 inches.

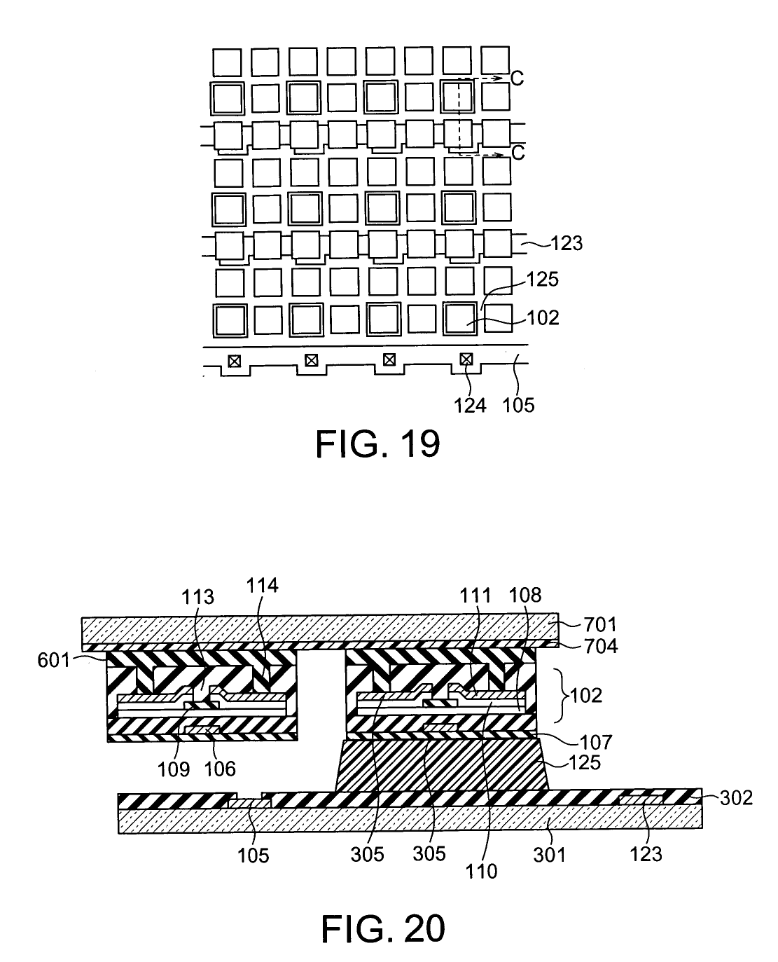

Thereafter, the TFTs 102 on the intermediate transfer substrate 701 are transferred onto the final transfer substrate 301. FIG. 19 is a drawing viewing the TFTs 102 on the intermediate transfer substrate 701 from above, at the time they are transferred onto the final transfer substrate 301. For the sake of easy understanding, the intermediate transfer substrate 701 is not shown in this drawing. FIG. 20 is a sectional view taken along line C-C of FIG. 19. As shown in FIG. 20, the intermediate transfer substrate 701 and the final transfer substrate 301 are held so that the TFTs 102 on the intermediate transfer substrate 701 are placed on the adhesion layer 125 on the final transfer substrate 301. Thereafter, a predetermined pressure is applied to the final transfer substrate 301 and the intermediate transfer substrate 701, and heat or light is emitted thereto from the outside to decrease the viscosity or adhesion force of the temporary adhesive layer 704. Then, the intermediate transfer substrate 701 is removed from the final transfer substrate 301, thereby transferring the TFTs from the intermediate transfer substrate 701 to the final transfer substrate 301.

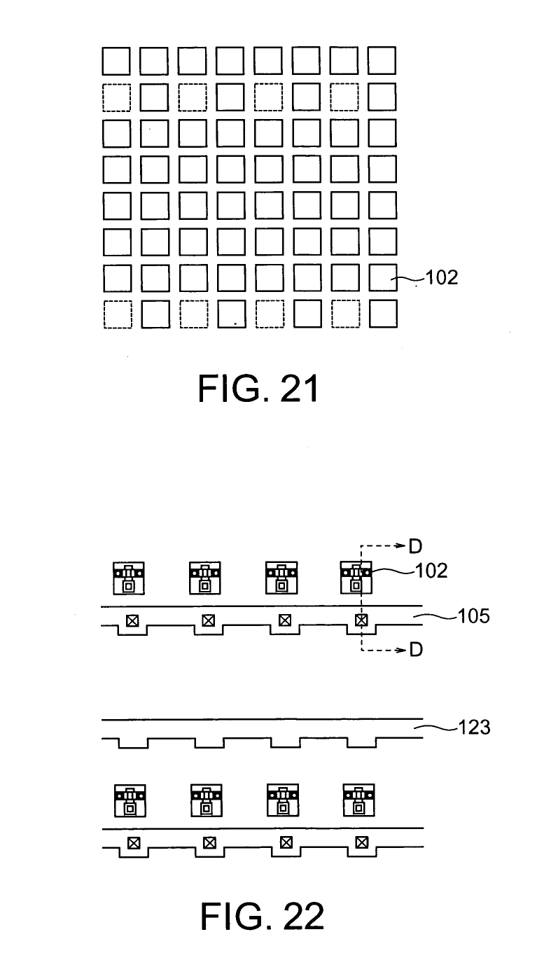

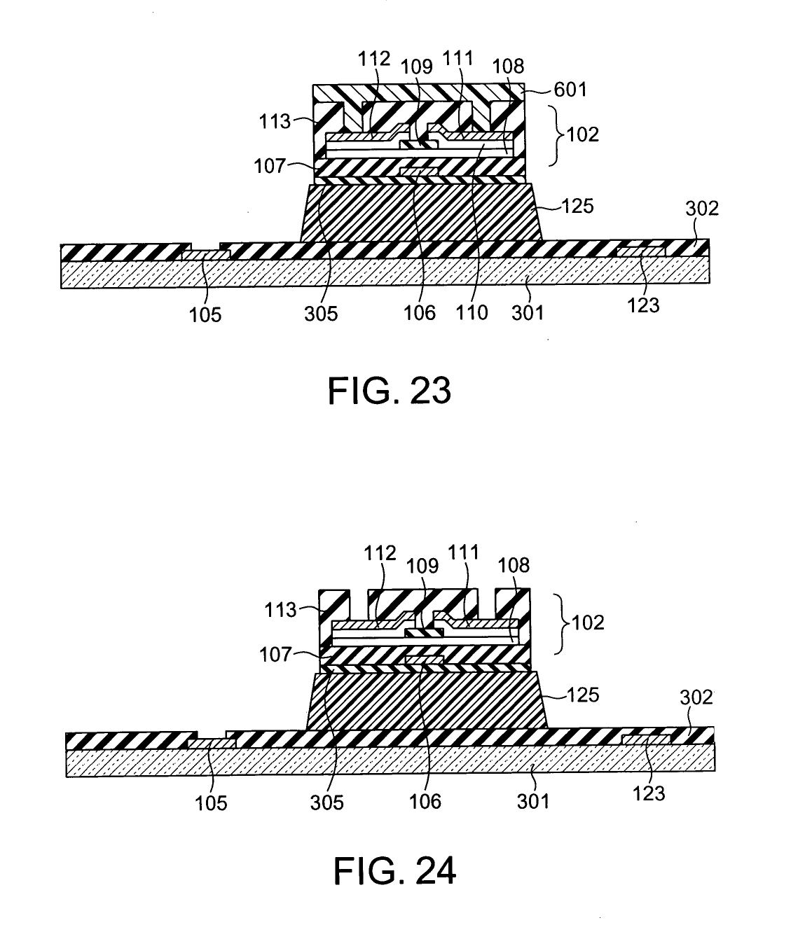

FIG. 21 shows a plan view of the intermediate transfer substrate 701 after the transfer is performed; FIG. 22 is a plan view of the final transfer substrate 301; and FIG. 23 is a sectional view taken along line D-D of FIG. 22. As shown in FIG. 21, one among twelve TFTs formed on the intermediate transfer substrate 701 is transferred onto the final transfer substrate 301, and removed from the intermediate transfer substrate 701. By repeating the aforementioned TFT transfer process, it is possible to selectively transfer the TFTs on all the adhesion layer portions of the final transfer substrate 301, thereby arranging the TFTs in a matrix form on the final transfer substrate 301.

Furthermore, as shown in FIG. 24, the protection layer 601 left on the TFTs 102 is removed by an ashing method in which plasma containing oxygen is irradiated, or by dissolving the workpiece in a solvent. In such a case, however, it is possible to select appropriate conditions so that no damage is caused to the interlayer insulating film 302 and the adhesion layer 125.

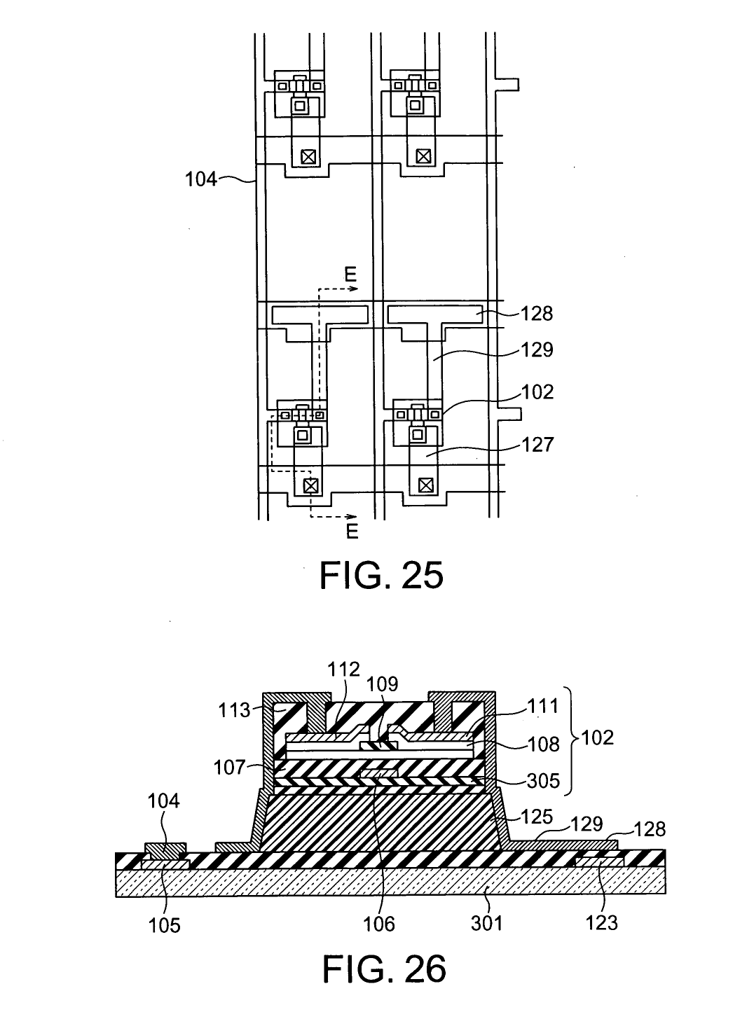

Thereafter, as shown in FIGS. 25-30, the signal lines 104, a flattening film 303, and pixel electrodes 103 are formed in this order on the final transfer substrate 301, on which the TFTs 102 are arranged in a matrix form. FIG. 25 is a plan view showing a part of a pixel region, and FIG. 26 is a sectional view taken along line E-E of FIG. 25. First, as shown in FIGS. 25 and 26, the signal lines 104 are formed of a material similar to the material of the scanning lines 105. The signal lines 104 are connected to the drain electrodes 112 of the TFTs 102. At the same time as the signal lines 104 are formed, there are formed contact wiring lines 127 for connecting the scanning lines 105 with gate electrodes 106 of the TFTs 102, storage capacitor electrodes 128, and contact wiring lines 129 for connecting the storage capacitor electrodes 128 with the source electrodes. Storage capacitance is generated between the storage capacitor lines 123 and the storage capacitor electrodes 128.

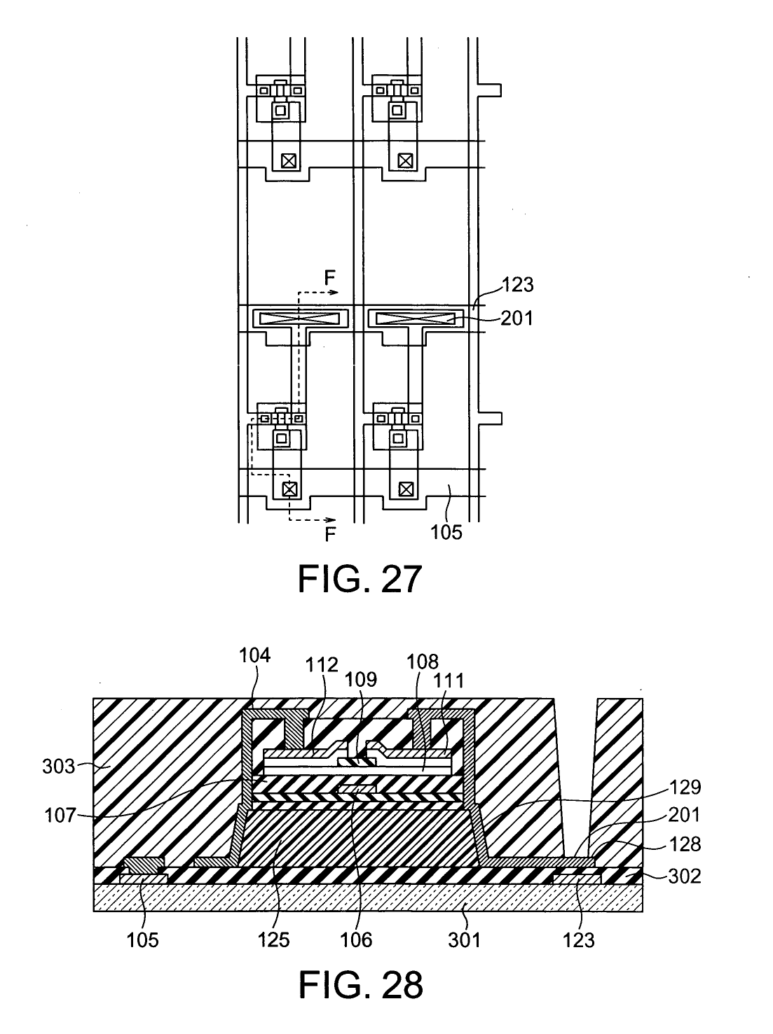

Next, as shown in FIGS. 27 and 28, the flattening film 303 is formed on the final transfer substrate 301 including the TFTs 102. FIG. 27 is a plan view showing the part of the pixel region, and FIG. 28 is a sectional view taken along line F-F of FIG. 27. The flattening film 303 is formed by applying an acrylic resin to have a thickness of 2 μm-20 μm and performing an annealing operation. The difference between the convexes and concaves of the flattening film is about 0.5 μm or less. For this purpose, an inorganic insulating film can be formed and polished to form the flattening film 303. A contact portion 201 is formed above each storage capacitor electrode of the flattening film 303 by, after the flattening film 303 is formed, applying a resist to the flattening film, performing exposure and development processing, and then performing etching processing. When a photosensitive resin material is used to form the flattening film 303, after the application of the flattening film 303, exposure and development processing can be performed.

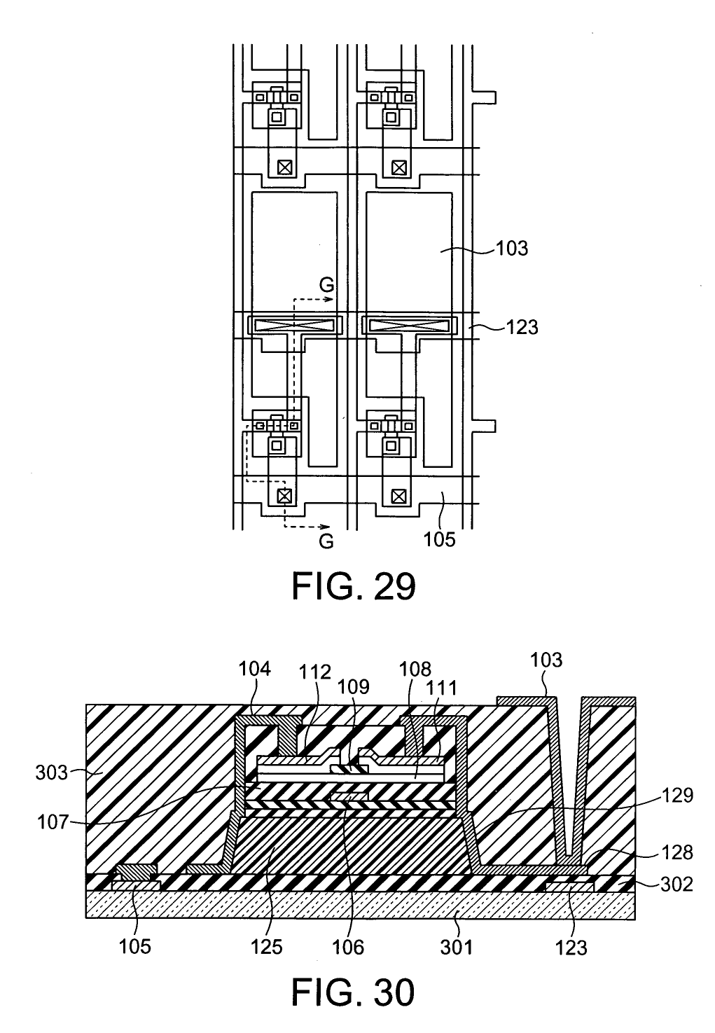

FIG. 29 is a plan view showing the part of the pixel region, and FIG. 30 is a sectional view taken along line G-G of FIG. 29. After the flattening film 303 is formed, an ITO (Indium Tin Oxide) film is formed by a sputtering method and patterned, thereby forming the pixel electrode 103 as shown in FIGS. 29 and 30.

The order of the formation of the wiring lines such as the scanning lines 105 and the signal lines 104, the formation of the adhesion layer 125, the formation of the through-holes of the interlayer insulating film 302, and the transfer of the elements from the intermediate transfer substrate 701 to the final transfer substrate 301 does not have to be the order of the first embodiment.

It is possible to obtain a flexible and large-size TFT-LCD, which is not limited by the size or the material of the substrate at the time of the forming of elements, by forming the liquid crystal display using the active matrix substrate formed through the aforementioned process.

Although a TFT-LCD using an active matrix substrate is taken as an example in this embodiment, the present invention is not limited to such an apparatus, but can be applied to display apparatuses other than LCDs such as organic EL displays and electrophoretic displays, devices using an active matrix substrate, such as CCDs, and thin film devices such as semiconductor lasers and an LEDs.

### Second Embodiment

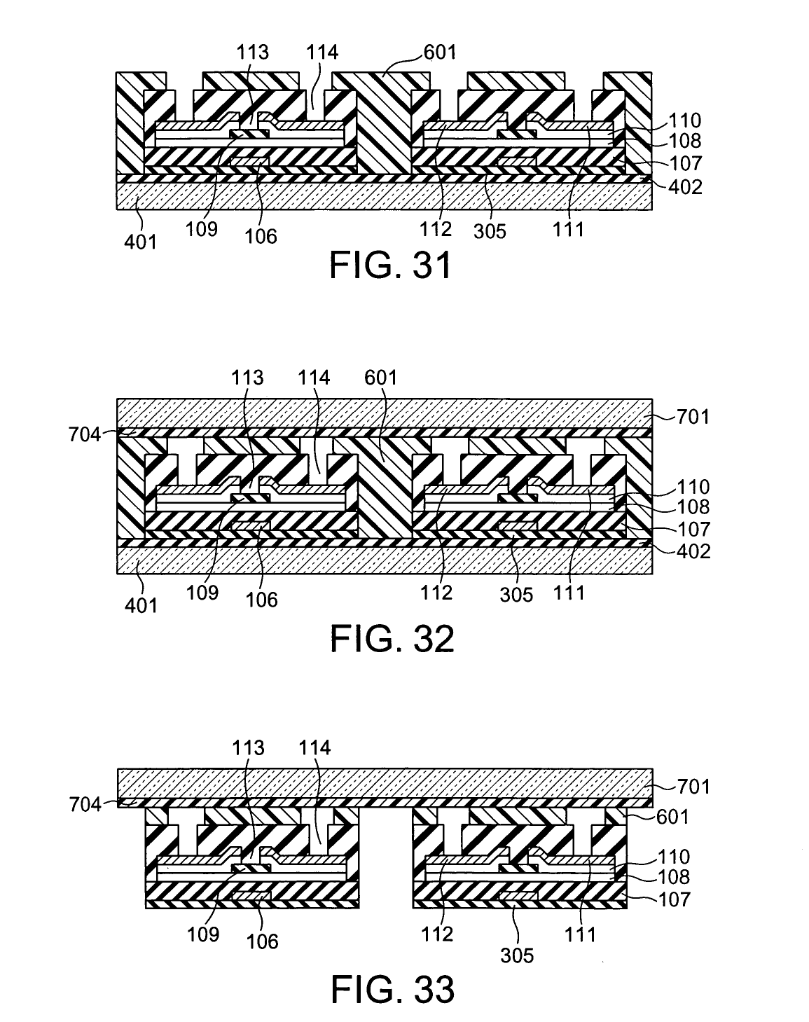

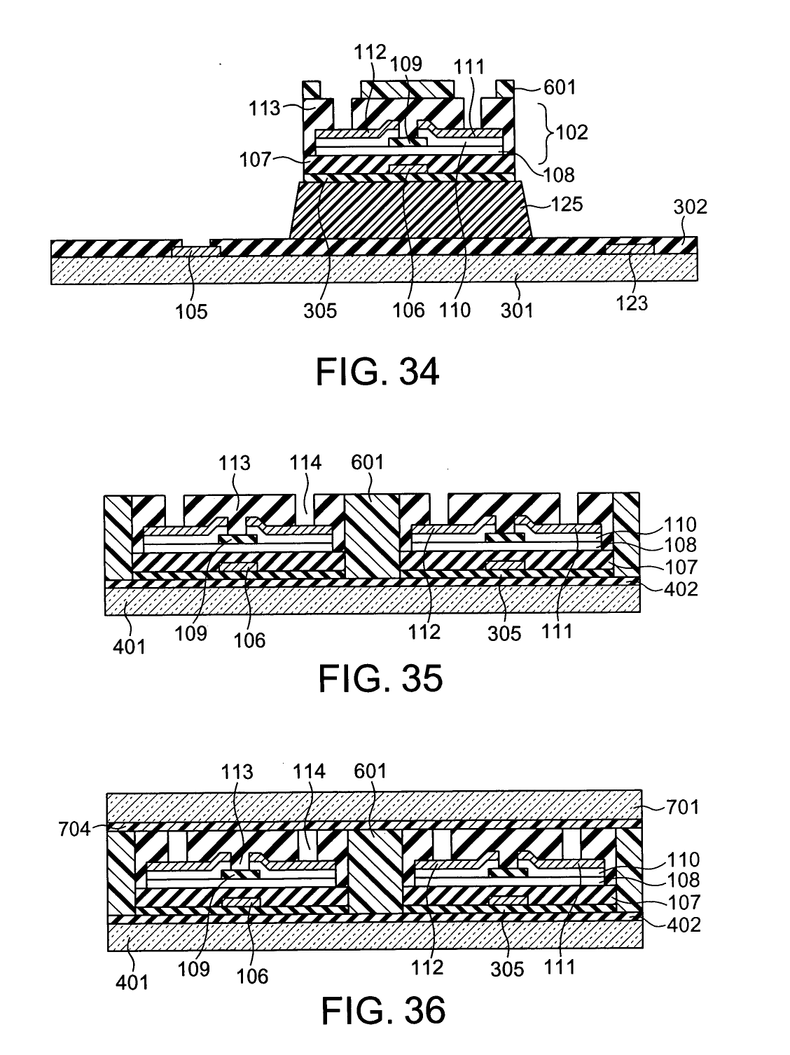

Next, a second embodiment will be described with reference to FIGS. 31-34. With respect to this embodiment, only the portions which are different from those of the first embodiment are described, and the descriptions of the other portions are omitted.

In this embodiment, the shape of a protection layer 601 on an element formation substrate 401 is different from that of the first embodiment.

The TFTs 102 are formed on the element formation substrate 401 in the same manner as the first embodiment until the step shown in FIG. 7, and then each TFT is separated in the direction along the plane of the element formation substrate 401.

Subsequently, as shown in FIG. 31, the protection layer 601 of an organic resin is formed in the regions of the element formation substrate 401 other than those above and in the vicinity of the contact holes 114 of the TFTs. This can be done by applying an organic resin to the entire surface of the element formation substrate 401, and then etching and removing only the portions around the contact holes 114 by photolithography processing, or by using a photosensitive organic resin to form the protection layer 601, and then exposing the organic resin to light in order to pattern the protection layer 601. In this embodiment, a mixed liquid containing a polyimide resin and a solvent is applied by a spin coating method, and the steps of exposure, development, and baking are performed to form the protection layer 601 of a polyimide resin having a thickness of 1 μm, which has openings only above and in the vicinity of the contact holes 114 as shown in FIG. 31. The protection layer 601 is formed between adjacent TFTS.

Thereafter, the element formation substrate 401, on which the TFTs 102 are formed, and the intermediate transfer substrate 701 are bonded together in the same manner as the first embodiment, and the TFTs 102 are transferred to the intermediate transfer substrate 701, as shown in FIG. 32. Also in this case, since there is the protection layer 601 of an organic resin between adjacent TFTs 102 in addition to the isolation layer 402, the isolation layer 402 and the TFTs 102 are unlikely to suffer damage in the substrate removing step shown in FIG. 33, as in the case of the first embodiment. It is possible to transfer the TFTs 102 to the intermediate transfer substrate 701 so as to be separated from each other in the plane of the substrate, as shown in FIG. 33, by removing the protection layer 601 formed between adjacent TFTs 102 through an ashing method or by using a solvent.

Since no protection layer 601 exists above the contact holes 114 of the TFTs 102 in this embodiment, even if the TFTs 102 are transferred to the final transfer substrate 301 in the same manner as the first embodiment, the step of removing the protection layer 601 for making contact holes between the source and drain electrodes 111 and 112 and the signal lines and the storage capacitor lines can be omitted after the TFTs 102 are transferred to the final transfer substrate 301. In the first embodiment, the protection layer 601 should be removed by oxygen plasma ashing or a solvent, so that the interlayer insulating film 302 and the adhesion layer 125 should be resistant to such processes. However, such a process is not necessary in this embodiment, so that the degree of freedom in the choice of the material of the interlayer insulating film 302 and the adhesion layer 125 can be increased.

After the TFTs 102 are transferred, the signal lines 104, the flattening film 303, and the pixel electrode 103 are formed on the final transfer substrate 301 in the same manner as the first embodiment (FIGS. 26-30). In this manner, it is possible to form an active matrix substrate.

### Third Embodiment

Next, a third embodiment will be described with reference to the drawings. With respect to this embodiment, only the portions which are different from those of the first embodiment will be described, and the descriptions of the other portions will be omitted.

As in the case of the second embodiment, the shape of the protection layer 601 formed on the element formation substrate 401 in this embodiment is different from that of the first embodiment.

The TFTs 102 are formed on the element formation substrate 401 in the same manner as the first embodiment until the step shown in FIG. 7, and then each TFT is separated in the direction in the plane of the element formation substrate 401.

Subsequently, as shown in FIG. 35, a protection layer 601 of an organic resin is formed on the element formation substrate 401 only at the portions between adjacent TFTs 102. The height of the surface of the protection layer 601 is substantially the same as the height of the surface of the TFTs 102. This can be done by utilizing the step between the TFTs 102, which are higher, and the portions between TFTs 102, and forming the protection layer 601 only at the desired portions by a spin coating method. Alternatively, first the protection layer 601 can be formed on the entire surface of the element formation substrate 401 including the portions above the TFTs 102, and then only the portions of the protection layer 601 above the TFTs 102 can be selectively removed by a polishing method or the like.

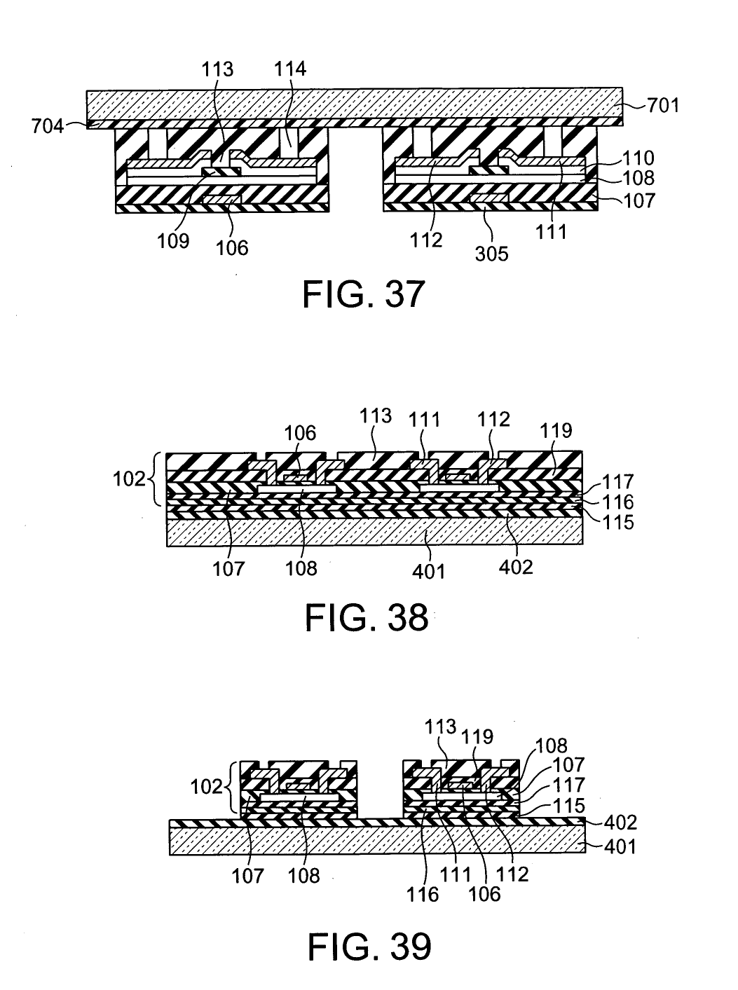

Thereafter, the element formation substrate 401 and the intermediate transfer substrate 701 are bonded together in the same manner as the first embodiment, and the TFTs 102 are transferred to the intermediate transfer substrate 701, as shown in FIG. 36. Also in this case, since there is the protection layer 601 of an organic resin between adjacent TFTs 102 in addition to the isolation layer 402, the isolation layer 402 and the TFTs 102 are unlikely to suffer damage in the substrate removing step, as in the case of the first embodiment. Furthermore, by removing the protection layer 601 formed between adjacent TFTs 102 through an ashing method or by using a solvent, it is possible to transfer the TFTs 102 to the intermediate transfer substrate 701 so that they are separated from each other in the plane of the substrate, as shown in FIG. 37.

The TFTs 102 are transferred to the final transfer substrate 301 in the same manner as the first embodiment. Since no protection layer 601 exists above the TFTs 102 in this embodiment, it is not necessary to remove the protection layer 601 after the TFTs 102 are transferred onto the final transfer substrate 301. Accordingly, the degree of freedom in the choice of the material of the interlayer insulating film 302 and the adhesion layer 125 can be increased.

Thereafter, the signal lines 104, the flattening film 303, and the pixel electrode 103 are formed on the final transfer substrate in the same manner as the first embodiment. In this manner, it is possible to form an active matrix substrate.

### Fourth Embodiment

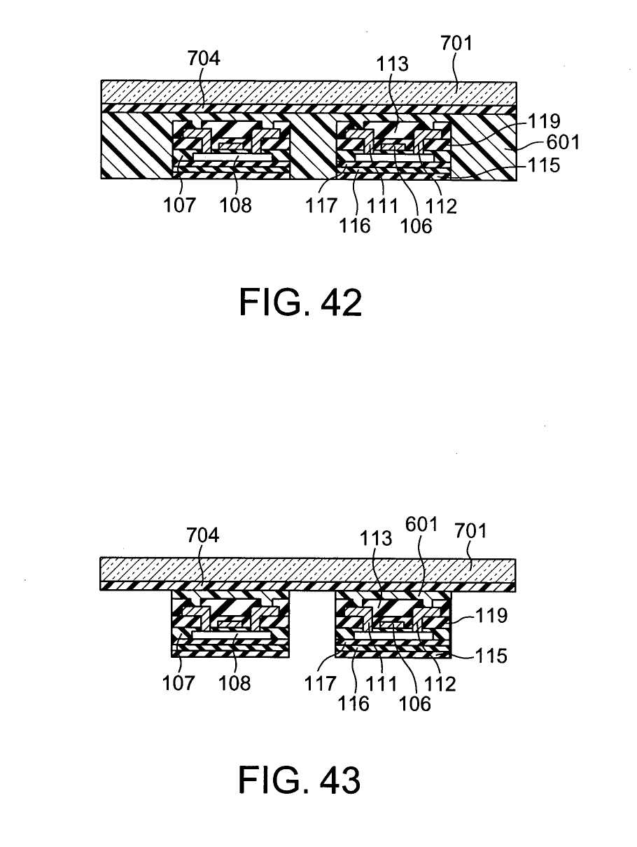

Next, a fourth embodiment will be described with reference to FIGS. 38-43. This embodiment differs from the first to third embodiments in that top gate type polycrystalline silicon TFTs are used as switching elements. There is no problem, however, if amorphous silicon TFTs are used. The same reference numerals are assigned to the portions common to those of the first to third embodiments.

First, as shown in FIG. 38, an isolation layer 402 having a thickness of about 50-200 nm is formed on an element formation substrate 401 of non-alkali glass. The material of the isolation layer 402 can be an insulating material such as a silicon-containing material, a metal, SiNx, AlOx, and TaOx, which are resistant to an etchant containing hydrofluoric acid. A first supporting layer 115 of SiOx having a thickness of about 10-20 nm, a second supporting layer 116 of SiNx having a thickness of about 50-200 nm, and a third supporting layer 117 of SiOx having a thickness of about 50-200 nm are sequentially formed on the isolation layer 402, and a semiconductor layer 108 of polycrystalline silicon thin film having a thickness of about 50-100 nm is formed on the third supporting layer 117. If necessary, boron, which serves as a p-type dopant, or phosphorus, which serves as an n-type dopant, is implanted into the semiconductor layer 108 through a ion doping method or the like, thereby controlling the carrier concentration.

Thereafter, a gate insulating film 107 of SiOx having a thickness of about 50-200 nm is formed on the surface of the third supporting layer 117 including the semiconductor layer 108. Subsequently, a metal film of MoW, Al, or the like is formed on the gate insulating film 107 and patterned, thereby forming a gate electrode 106. In this embodiment, the thickness of the gate electrode 106 is, e.g., 300 nm, and the gate length is, e.g., about 5 μm. An interlayer insulating film 119 of SiOx is formed on the surface of the gate insulating film 107 including the gate electrode 106. A source electrode 111 and a drain electrode 112 are formed so as to penetrate the interlayer insulating film 119 and the gate insulating film 107 to connect to the source and drain regions of the semiconductor layer 108 sandwiching the gate electrode 106. In this manner, the TFTs 102 are formed. After the source electrode 111 and the drain electrode 112 are formed, a passivation film 113 of SiNx or the like is formed on the surface of the interlayer insulating film 119, and contact holes are formed through the passivation film 113 so as to expose the surfaces of the source electrode 111 and the drain electrode 112.

Subsequently, as shown in FIG. 39, portions of the passivation film 113, the interlayer insulating film 119, the gate insulating film 107, the third supporting layer 117, the second supporting layer 116, and the first supporting layer 115 where no TFT 102 is formed are selectively etched and removed by performing anisotropy etching from the surface side of the substrate, thereby separating the respective TFTs 102. At this time, the layers are etched by wet etching with an etchant containing a hydrofluoric acid such as BHF until the third supporting layer 117, using as a mask a resist pattern having been exposed to light using a predetermined mask. Thereafter, dry etching of the second supporting layer 116 with a fluorine-containing gas such as sulfur hexafluoride gas and carbon tetrafluoride gas, and wet etching of the first supporting layer 115 using BHF or the like are performed to pattern these layers using the patterned third supporting layer 117 as a mask. The isolation layer 402 can be used as an etching stopper when the first supporting layer 115 is etched. With the existence of the isolation layer 402, the etching rate of the second supporting layer 116 can be controlled, so that the second supporting layer 116 can be etched at the same time as the first supporting layer 115.

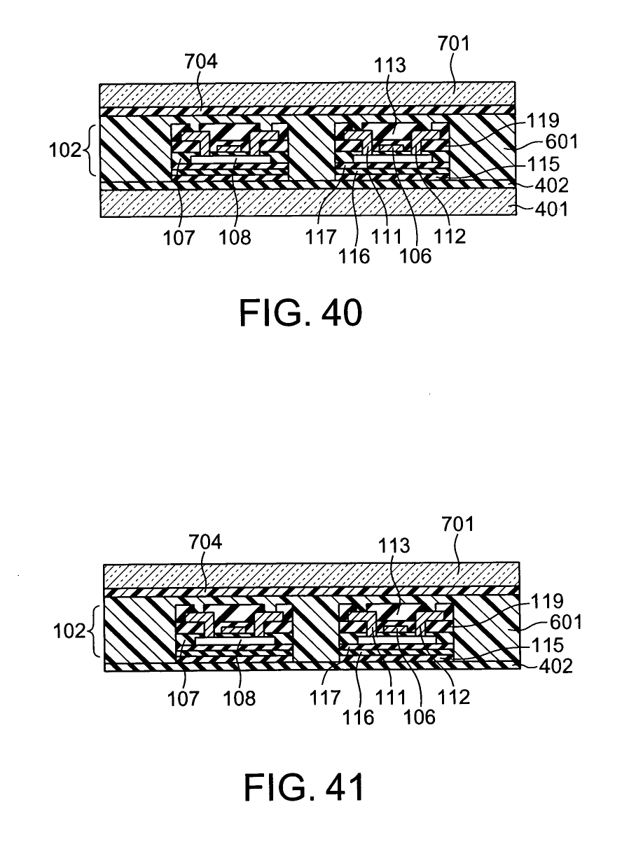

Subsequently, as shown in FIG. 40, a protection layer 601 of an organic resin is formed so as to fill in each space between adjacent TFTs 102, which have been separated. The surface of the protection layer 601 is substantially flat. In this case, a mixed liquid containing a polyimide resin and a solvent is coated by a spin coating method, and then the exposing step, the developing step, and the baking step to volatize the solvent are performed to flatten the surface. After the protection layer 601 is formed, the surface of the protection layer 601 is bonded with an intermediate transfer substrate 701 with a temporary adhesive layer 704 being provided therebetween, as in the case of other examples.

After the surface of the protection layer 601 is bonded with the intermediate transfer substrate 701, the element formation substrate 401 is etched and removed using an etchant containing a hydrofluoric acid, as shown in FIG. 41. Since the isolation layer is resistant to a hydrofluoric acid, the isolation layer serves as an etching stopper when the element formation substrate is etched. In addition to the isolation layer 402, there is the protection layer 601 of an organic resin between adjacent TFTs. Accordingly, the strength of this portion is increased as compared to the case where only the isolation layer 402 exists, so that it becomes unlikely that damage caused by crack or peel-off occurs due to a chemical factor such as exposure to an etchant, or a physical factor such as heat or stress. As a result, the element formation substrate 401 can be completely removed without causing the TFTs 102 to suffer damage from the etchant used in this step.

Subsequently, the isolation layer 402 is etched using another etchant. The etching method can be either wet etching using TMAH or the like, or dry etching such as reactive ion etching and chemical dry etching using a fluorine-containing gas such as sulfur hexafluoride gas, carbon tetrafluoride gas, etc. Since each TFT 102 is separated from the isolation layer 402 in a state of being surrounded by the protection layer 601, it is possible to prevent each TFT 102 from being affected by the etchant of wet etching, or the gas of dry etching.

Thereafter, the protection layer 601 is processed using O₂ plasma or wet etching, using the first supporting layer 115, which is patterned to have the size of each TFT 102, so that it is possible to remove the protection layer from each TFT in the plane of the substrate, as shown in FIG. 43. Then, as in the case of the steps after the step shown in FIG. 19 of the first embodiment, the TFTs 102 are bonded with an interlayer insulating film 302 on a final transfer substrate 301 to complete the active matrix substrate.

When the supporting layer having the aforementioned structure is used, the selectivity in a dry etching step using a fluorine-containing gas is improved since when the isolation layer 402 is etched, the selectivity with respect to the silicon oxide layer can be considered instead of the selectivity with respect to the silicon nitride layer. As the result, the silicon nitride layer can be left with certainty, thereby improving the passivation effect with respect to the back surface to improve the reliability of the transistor.

Furthermore, when the insulating layer is processed to have an island structure on the original substrate, it is possible to easily control the selectivity between the silicon nitride layer and the isolation layer. Accordingly, it is possible to prevent the isolation layer from being damaged and becoming a defect when the substrate is removed.

Although stress may sometimes be increased in a silicon nitride layer, it is possible to control the degree of stress by inserting the silicon nitride layer between upper and lower silicon oxide layers, thereby decreasing the occurrence of cracks at the time of removing the substrate and the occurrence of warping of elements after the substrate is removed.

In each embodiment of a method of manufacturing a thin film element according to the present invention, it is possible to prevent the problem that elements suffer damage during an element transfer procedure wherein after elements are formed on the substrate, the elements are separated from each other in the plane of the substrate, the element formation substrate is removed, and then the elements are transferred onto the final transfer substrate.

It should be noted that the present invention is not limited to the aforementioned embodiments, but can be modified without departing from the spirit and scope thereof when the present invention is carried out. Furthermore, it is possible to create variations of the present invention by optionally combining the constituent elements of the aforementioned embodiment. Some of the constituent elements of the aforementioned embodiments can be omitted. Furthermore, some constituent elements can be selected from different embodiment and combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A method of manufacturing a thin film element comprising:
sequentially forming an isolation layer and an undercoat layer on an element formation substrate;
forming a plurality of thin film elements on the undercoat layer;
separating the thin film elements in a plane of the substrate with the isolation layer being left on the entire surface of the element formation substrate;
forming a protection layer between adjacent thin film elements, which have been separated from each other;
temporarily bonding an intermediate transfer substrate to the thin film elements at a side opposite to the element formation substrate; and
removing the element formation substrate, thereby transferring the thin film elements onto the intermediate transfer substrate.

2. The method of manufacturing a thin film element according to claim 1, further comprising:
removing the isolation layer after the element formation substrate is removed.

3. The method of manufacturing a thin film element according to claim 1, wherein the transferring of the thin film elements onto the intermediate transfer substrate includes removing the protection layer between the thin film elements.

4. The method of manufacturing a thin film element according to claim 3, further comprising:
transferring the thin film elements onto a final transfer substrate after the protection layer between the thin film elements is removed.

5. The method of manufacturing a thin film element according to claim 4, wherein the transferring of the thin film elements to the final transfer substrate includes repeating the transferring of some selected thin film elements onto the final transfer substrate.

6. The method of manufacturing a thin film element according to claim 5, wherein the thin film elements are thin film transistors.

7. The method of manufacturing a thin film element according to claim 6, wherein the thin film elements are thin film transistors including a semiconductor layer of amorphous silicon.

8. The method of manufacturing a thin film element according to claim 6, wherein the thin film elements are thin film transistors including a semiconductor layer of polycrystalline silicon.

9. The method of manufacturing a thin film element according to claim 1, wherein the protection layer is formed on the entire surface of the element formation substrate.

10. The method of manufacturing a thin film element according to claim 9, wherein the intermediate transfer substrate is bonded to the protection layer.

11. The method of manufacturing a thin film element according to claim 10, further comprising:
removing the isolation layer after the element formation substrate is removed.

12. The method of manufacturing a thin film element according to claim 10, wherein the transferring of the thin film elements onto the intermediate transfer substrate includes removing the protection layer between the thin film elements.

13. The method of manufacturing a thin film element according to claim 12, further comprising:
transferring the thin film elements onto a final transfer substrate after the protection layer between the thin film elements is removed.

14. The method of manufacturing a thin film element according to claim 13, wherein the transferring of the thin film elements onto the final transfer substrate includes repeating the transferring of selected thin film element onto the final transfer substrate.

15. The method of manufacturing a thin film element according to claim 9, wherein the thin film elements are thin film transistors.

16. The method of manufacturing a thin film element according to claim 15, wherein the thin film elements are thin film transistors including a semiconductor layer of amorphous silicon.

17. The method of manufacturing a thin film element according to claim 15, wherein the thin film elements are thin film transistors including a semiconductor layer of polycrystalline silicon.

18. The method of manufacturing a thin film element according to claim 1, wherein the protection layer is formed of a material selected from the group consisting of a novolac resin, a polyimide resin, an acrylic resin, a cresol resin, a toluene resin, a phenol resin, a vinyl resin, an epoxy resin, an alkyd resin, a vinyl acetate resin, a melamine resin, a styrene resin, a fluorine resin, and a resin containing polynorbornene, poly-parahydroxystyrene, and methacrylate.

19. The method of manufacturing a thin film element according to claim 1, wherein the isolation layer is formed of a material selected from the group consisting of amorphous silicon, a metal oxide, and silicon nitride.

20. The method of manufacturing a thin film element according to claim 1, wherein the undercoat layer is formed of silicon oxide or silicon nitride.

21. The method of manufacturing a thin film element according to claim 1, wherein the separating of the thin film elements includes removing the undercoat layer between the thin film elements.
